(19) United States
(12) Patent Application Publication
(10) Pub. No.: US 2008/0020568 A1
(43) Pub. Date: Jan. 24, 2008

(54) Semiconductor device having a silicide layer and method of fabricating the same

(75) Inventor: In Hee Jang, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU HITEK CO., LTD.

(21) Appl. No.: 11/826,925

(22) Filed: Jul. 19, 2007

(30) Foreign Application Priority Data
Jul. 20, 2006 (KR) 10-2006-0068018

(51) Int. Cl. H01L 21/477; H01L 23/58

(52) U.S. Cl. 438/664; 257/636; 257/E21.497

(57) ABSTRACT

A method of fabricating a semiconductor device having a silicide layer, including forming an interlayer insulating layer on an entire surface of a semiconductor substrate, forming a contact hole in the interlayer insulating layer, sequentially forming a silicide material and a barrier metal layer over the interlayer insulating layer including the contact hole, and performing an annealing process on the interlayer insulating layer to thereby form the silicide layer between a bottom surface of the interlayer insulating layer, which is exposed by the contact hole, and the silicide material.

### RELATED APPLICATION

The application is based upon and claims the benefit of priority to Korean Application No. 10-2006-0068018 filed on Jul. 20, 2006, the entire contents of which are incorporated herein by reference.

### TECHNICAL FIELD

The present invention relates to a semiconductor device and a method of fabricating the same. In particular, the present invention relates to a semiconductor device having a silicide layer and a method of forming the same.

### DISCUSSION OF RELATED ART

In recent years, as the degree of integration of semiconductor devices increases, the width of a metal line decreases and sheet resistance of the metal line increases accordingly. If the sheet resistance of the metal line increases, signal transmission time of components within an integrated circuit is delayed. To prevent this problem, high melting-point silicide material, which has a low resistivity and is stable at high temperature, is added to not only the gate electrode of a transistor, but also the source/drain junction, or the like in order to lower sheet resistance and contact resistance of the metal line. Rare earth metal that reacts to silicon (Si) is generally used as such silicide material. The rare earth metal, for example, includes silicide such as tungsten silicide (WSi₂), titanium silicide (TiSi₂), and cobalt silicide (CoSi₂).

FIG. 1 is a vertical cross-sectional view of a conventional semiconductor device having a silicide layer.

As shown in FIG. 1, the conventional semiconductor device having the silicide layer includes field regions 12 formed in a silicon substrate 10 as a semiconductor substrate, a gate electrode 16 formed over silicon substrate 10 in which field regions 12 are formed with a gate insulating layer 14 intervened therebetween, Lightly Doped Drain (LDD) regions 18 formed in silicon substrate 10 at the edges of gate electrode 16, a spacer wall 20 formed on the sidewalls of gate electrode 16, source/drain regions 22 formed in silicon substrate 10 at the edges of spacer wall 20, and a silicide layer 26a formed on the top surfaces of gate electrode 16 and source/drain regions 22.

The conventional semiconductor device further includes a contact electrode 34. Contact electrode 34 is vertically connected to silicide layer 26a of source/drain region 22 through the contact hole of interlayer insulating layer 28 on the entire surface of silicon substrate 10 on which silicide layer 26a is formed. In addition, contact electrode 34 further includes a barrier metal layer 32 formed on the inner sidewall of the contact hole.

FIGS. 2A to 2G are cross-sectional views illustrating a conventional method of fabricating the semiconductor device having the silicide layer.

The conventional method will be described below with reference to FIGS. 2A to 2G.

Referring to FIG. 2A, a semiconductor device process, for example, a MOS transistor formation process is performed on a silicon substrate 10 as a semiconductor substrate.

Field regions 12 to define active regions are formed on silicon substrate 10. More specifically, for example, trenches are formed in silicon substrate 10 by etching silicon substrate 10 to a specific depth. The trenches are then filled with insulating material. After that, insulating material is polished by a Chemical Mechanical Polishing (CMP) process to thereby form field regions 12.

An insulating layer and a gate conductive layer are sequentially stacked on silicon substrate 10 in which field regions 12 are defined, and are then patterned to form a gate electrode 16 with a gate insulating layer 14 intervened between silicon substrate 10 and gate electrode 16. The gate conductive layer may be formed from any one of polysilicon into which an impurity is doped, such as, SiGe, cobalt (Co), tungsten (W), titanium (Ti), nickel (Ni), tantalum (Ta), titanium nitride (TiN), tantalum nitride (TaN), and tungsten nitride (WN).

LDD regions 18 are formed by performing a low concentration ion implant process using gate electrode 16 as an ion implant mask (for example, by implanting an N-type dopant of a low concentration). Insulating material, such as a silicon nitride (SiN) or silicon nitride oxide (SiON) film, is deposited on the entire surface of silicon substrate 10 and is then dry etched to form a spacer wall 20 on the sidewalls of gate electrode 16.

A high-concentration ion implant process using spacer wall 20 and gate electrode 16 as ion implant masks is performed to form source/drain regions 22. Each of source/drain regions 22 has a LDD structure including LDD region 18 of a low concentration on the surface of the substrate. Subsequently, as shown in FIGS. 2B and 2C, silicide blocking material 24, for example, a TEOS (tetra ethyl ortho silicate) film, is thinly deposited over silicon substrate 10 in which semiconductor elements, such as a MOS transistor, are formed. Silicide blocking material 24 is then dry etched to form a silicide blocking layer 24a on the sidewalls of spacer wall 20 and on the top surface of field regions 12.

Referring to FIGS. 2D and 2E, silicide material 26 is deposited on the entire surface of substrate 10 having silicide blocking layer 24a formed thereon. An annealing process is then performed on silicide material 26 to form silicide layers 26a on gate electrode 16 without having silicide blocking layer 24a and over source/drain regions 22. In this case, silicide material 26 may be made of metal, such as cobalt (Co), titanium (Ti), nickel (Ni), tungsten (W), platinum (Pt), or rare earth metal such as hafnium (Hf) or palladium (Pd), or any one of alloys thereof. Further, silicide layer 26a can be made of, for example, Tungsten silicide (WSi₂), titanium silicide (TiSi₂) or cobalt silicide (CoSi).

Thereafter, silicide material 26 and silicide blocking layer 24a, which have not been silicidized by silicide blocking layer 24a, are removed by a process such as cleaning.

Next, as shown in FIG. 2F, insulating material, such as boron-phosphorus silicate glass (BPSG) or phosphorus silicate glass (PSG), is thickly deposited on the entire surface of silicon substrate 10 in which silicide layer 26a is formed, thus forming an interlayer insulating layer 28 for insulating between the elements. Photo and etch processes using a contact mask are performed on interlayer insulating layer 28 to form contact holes 30 through which the surfaces of silicide layers 26a on source/drain regions 22 are exposed.

Subsequently, as shown in FIG. 2G, Ti/TiN as a barrier metal layer 32 are thinly deposited in contact holes 30 of interlayer insulating layer 28. Conductive material, for example, doped polysilicon or metal, such as tungsten (W), is deposited to fully fill the contact holes. Barrier metal layer 32 and the conductive material are fully removed from the surface of interlayer insulating layer 28 by means of a CMP process. Accordingly, the contact holes are gap filled to form contact electrodes 34, which are vertically connected to silicide layers 26a of source/drain regions 22.

In the conventional method of fabricating the silicide layer in the semiconductor device, as described above, silicide layer 26a is silicidized by the reaction of metal of the silicide material, with the silicon on gate electrode region 16 and source/drain region 22 through the annealing process, while silicide blocking layer 24a is not silicidized even if it reacts to the metal of the silicide material.

Therefore, in the conventional silicide layer fabrication method, in order to form the silicide layer in a specific region of the semiconductor device, the process of forming silicide blocking layer 24a is performed on regions other than the specific region. To do so, sheet resistance and contact resistance of a portion in which the silicide layer is formed to be lowered.

However, because additional processes of depositing and patterning the silicide blocking layer are performed before the silicide layer formation process, there is a disadvantage in that an overall formation process of the semiconductor device is complicated.

### BRIEF SUMMARY

Consistent with the present invention, there is provided a semiconductor device having a silicide layer and a method of fabricating the same, which is capable of simplifying a silicide formation process by performing both a barrier metal layer formation process and a silicide process at the same time. Consistent with the present invention, there is provided a semiconductor device, including:

an interlayer insulating layer formed on an entire surface of a semiconductor substrate;

a contact hole formed in the interlayer insulating layer;

a silicide material and a barrier metal layer sequentially stacked over the interlayer insulating layer including the contact hole; and

a silicide layer formed between a bottom surface of the interlayer insulating layer, which is exposed by the contact hole, and the silicide material.

Consistent with another aspect of the present invention, there is provided a method of fabricating a semiconductor device having a silicide layer, including:

forming an interlayer insulating layer on an entire surface of a semiconductor substrate;

forming a contact hole in the interlayer insulating layer;

sequentially forming a silicide material and a barrier metal layer over the interlayer insulating layer including the contact hole; and

performing an annealing process on the interlayer insulating layer to form a silicide layer between a bottom surface of the interlayer insulating layer, which is exposed by the contact hole, and the silicide material.

### BRIEF DESCRIPTION OF THE DRAWINGS

Other objects and features consistent with the present invention will become apparent from the following description of preferred embodiments given in conjunction with the accompanying drawings. In the drawings:

FIG. 1 is a vertical cross-sectional view of a conventional semiconductor device having a silicide layer;

FIGS. 2A to 2G are cross-sectional views illustrating a conventional method of fabricating the semiconductor device having the silicide layer;

FIG. 3 is a vertical cross-sectional view of a semiconductor device having a silicide layer in accordance with an embodiment consistent with the present invention; and

FIGS. 4A to 4E are cross-sectional views illustrating a method of fabricating the semiconductor device having the silicide layer in accordance with an embodiment consistent with the present invention.

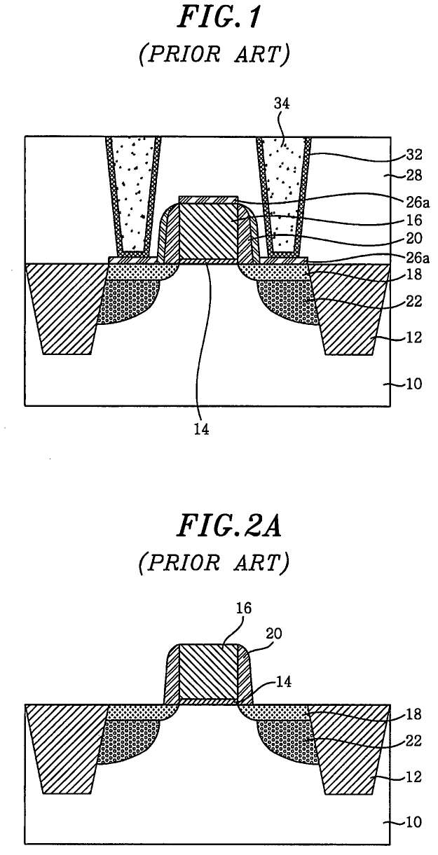

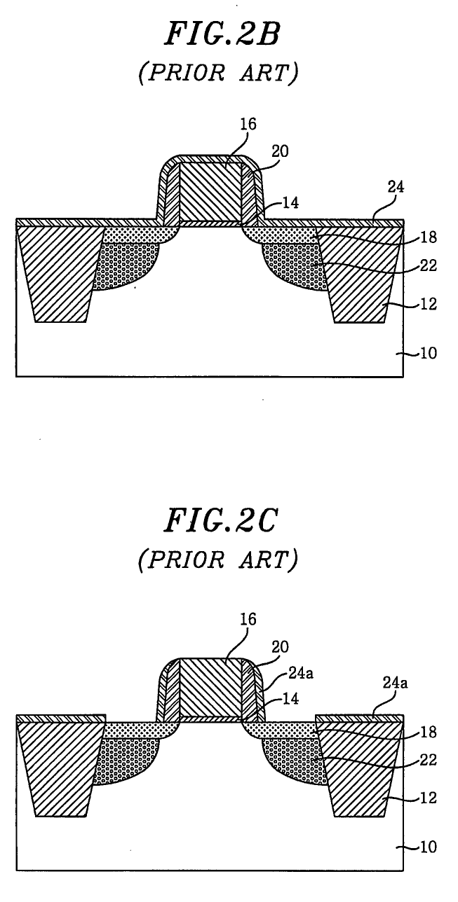

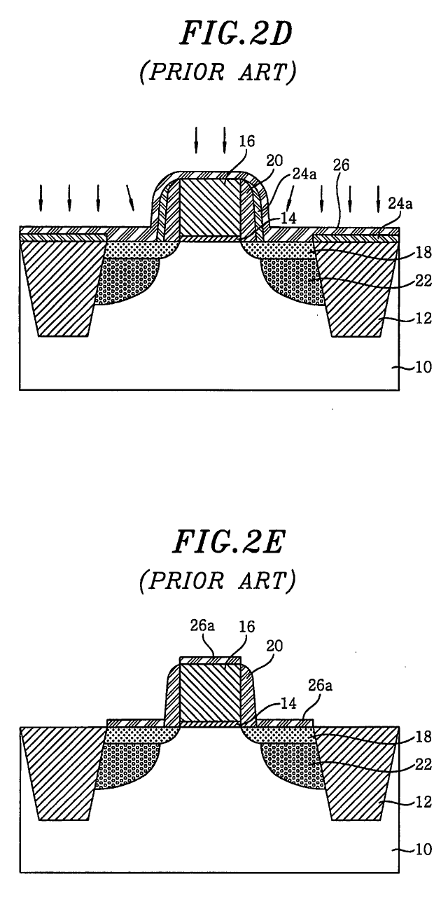

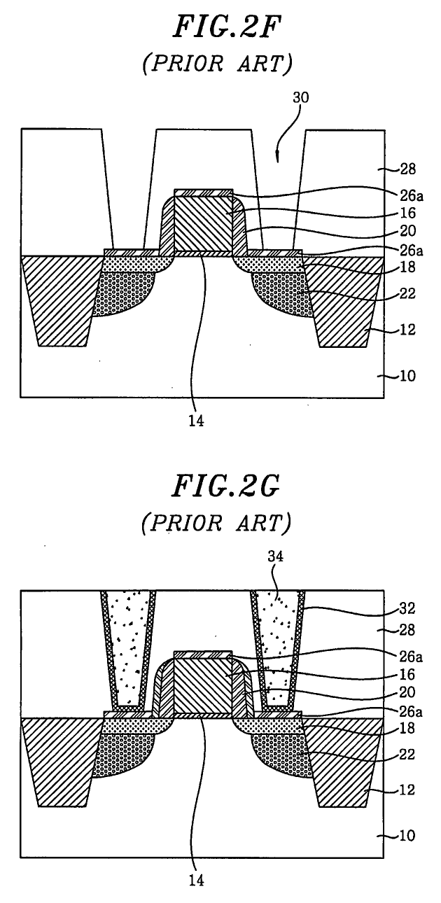

### DETAILED DESCRIPTION

Hereinafter, embodiments consistent with the present invention will be described in detail with reference to the accompanying drawings so that they can be readily implemented by those skilled in the art.

FIG. 3 is a vertical cross-sectional view of a semiconductor device having a silicide layer in accordance with an embodiment consistent with the present invention.

As shown in FIG. 3, the semiconductor device having the silicide layer includes field regions 102 formed in a silicon substrate 100 as a semiconductor substrate, a gate electrode 106 formed over silicon substrate 100 in which field regions 102 are formed with a gate insulating layer 104 intervened therebetween, LDD regions 108 formed in silicon substrate 100 at the edges of gate electrode 106, a spacer wall 110 formed on the sidewalls of gate electrode 106, and source/drain regions 112 formed in silicon substrate 100 at the edges of spacer wall 110.

The semiconductor device further includes an interlayer insulating layer 114 formed on the entire surface of silicon substrate 100 in which gate electrode 106 and source/drain regions 112 are formed, and a silicide material 118 and a barrier metal layer 120, which are sequentially, thinly formed on the inner sidewalls of the contact holes of interlayer insulating layer 114. In this case, it is preferable that the deposition thickness of silicide material 118 ranges from 100 to 150 angstrom. In the case where barrier metal layer 120 is comprised of Ti/TiN, Ti is preferably to have a thickness of 200 to 300 angstrom and TiN is preferably formed to have a thickness of 50 angstrom.

The semiconductor device consistent with the present invention further includes silicide layers 122 and contact electrodes 124. Silicide layer 122 is formed between the bottom surface (that is, source/drain region 112) of interlayer insulating layer 114, which is exposed by the contact hole and silicide material 118. Contact electrode 124 gap-fills the contact hole of interlayer insulating layer 114 and is vertically connected to source/drain region 112 through silicide layer 122, silicide material 118 and barrier metal layer 120.

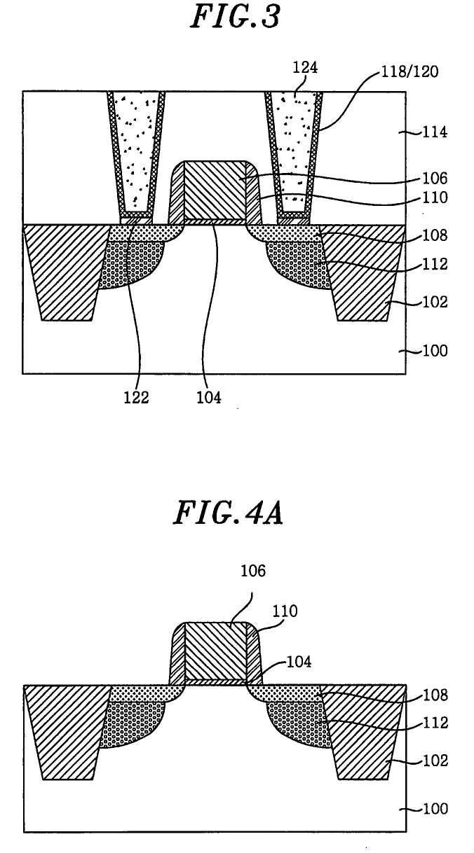

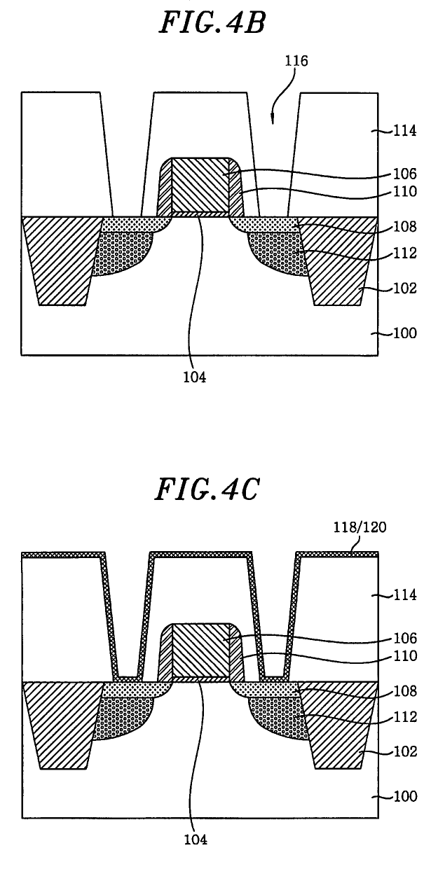

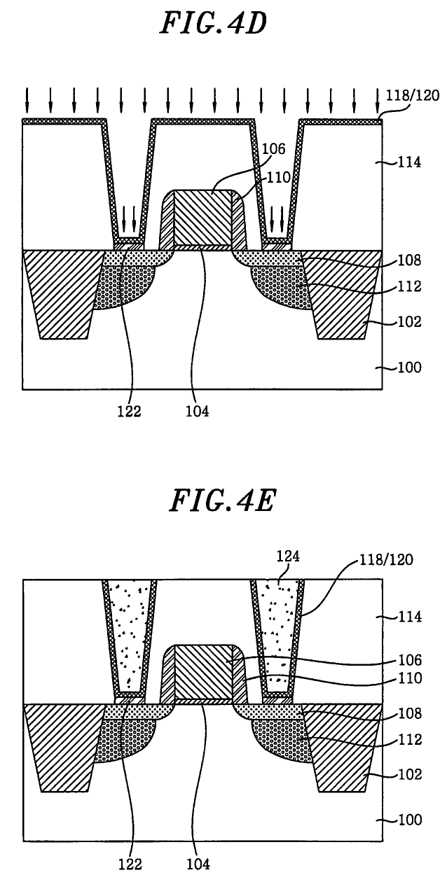

FIGS. 4A to 4E are cross-sectional views illustrating a method of fabricating the semiconductor device having the silicide layer in accordance with an embodiment consistent with the present invention.

Referring now to FIG. 4A, a semiconductor device process, for example, a MOS transistor formation process is performed on silicon substrate 100 as the semiconductor substrate.

Field regions 102 to define active regions are formed on silicon substrate 100. More specifically, for example, trenches are formed in silicon substrate 100 by etching silicon substrate 100 to a specific depth. The trenches are filled with insulating material. The insulating material is polished by a CMP process to form field regions 102.

An insulating layer and a gate conductive layer are sequentially stacked on silicon substrate 100 in which field regions 102 are defined, and are then patterned to form a gate electrode 106 with a gate insulating layer 104 intervened between silicon substrate 100 and gate electrode 106. The gate conductive layer can be formed from any one of polysilicon into which an impurity is doped, for example, SiGe, cobalt (Co), tungsten (W), titanium (Ti), nickel (Ni), tantalum (Ta), titanium nitride (TiN), tantalum nitride (TaN), and tungsten nitride (WN).

LDD regions 108 are formed by performing a low concentration ion implant process using gate electrode 106 as an ion implant mask (for example, by implanting an N type dopant of a low concentration). Insulating material, such as a SiN or SiON film, is deposited on the entire surface of silicon substrate 100 and is then dry etched to form a spacer wall 110 on the sidewalls of gate electrode 106.

A high-concentration ion implant process (for example, by implanting an N type dopant of a high concentration) using spacer wall 110 and gate electrode 106 as ion implant masks is performed to form source/drain regions 112. Each of source/drain regions 112 has a LDD structure including LDD region 108 of a low concentration on the surface of the substrate.

Referring to FIG. 4B, insulating material, such as BPSG or PSG, is thickly deposited on the entire surface of silicon substrate 100 in which semiconductor elements such as MOS transistors are formed, thus forming interlayer insulating layer 114 for insulating between the elements.

Photo and etch processes employing a contact mask are then performed on interlayer insulating layer 114 to form contact holes 116 through which the surfaces of source/drain regions 112 are exposed.

Thereafter, referring to FIG. 4C, silicide material 118 is thinly deposited on the entire surface of interlayer insulating layer 114 including contact holes 116. In this case, silicide material 26 can be formed of metal, such as cobalt (Co), titanium (Ti), nickel (Ni), tungsten (W), platinum (Pt), or rare earth metal such as hafnium (Hf) or palladium (Pd), or any one of alloys thereof. The deposition thickness of silicide material 118 ranges from 100 to 150 angstrom.

Barrier metal layer 120 is thinly deposited on silicide material 118. For example, barrier metal layer 120 may be formed from metal, such as Ti, Ta, TiN, TaN, Ti/TiN or Ta/TaN. In the case where barrier metal layer 120 is formed of Ti/TiN, it is preferable that Ti is formed to have a thickness of 200 to 300 angstrom and TiN is formed to have a thickness of 50 angstrom. In this case, silicide material 118 is preferably formed of cobalt (Co) having a good adhesion characteristic with Ti/TiN.

Referring next to FIG. 4D, an annealing process is performed to form silicide layer 122 between the bottom surface (that is, source/drain region 112) of interlayer insulating layer 114, which is exposed by the contact hole, and silicide material 118. For example, silicide layer 122 may be formed of WSi₂, TiSi₂, CoSi or the like.

The annealing process can be performed in rapid thermal annealing (RTA) equipment under an inert gas atmosphere, such as N₂, at a temperature of 700 to 900 Celsius degrees (for example, about 800 Celsius degrees) in order to form silicide layers 122 through the reaction of metal of the silicide material with silicon of source/drain region 112.

Thereafter, a temperature of 200 to 500 Celsius degrees is maintained in annealing equipment, such as a furnace, for a predetermined period of time.

Referring to FIG. 4E, conductive material, for example, doped polysilicon or metal such as tungsten (W) is deposited so that the contact holes are completely gap-filled. Silicide material 118, barrier metal layer 120, and the conductive material are fully removed from the top surface of interlayer insulating layer 114 by means of a CMP process. Accordingly, the contact holes of interlayer insulating layer 114 are gap-filled to form contact electrodes 124. In this case, contact electrodes 124 are vertically connected to source/drain regions 112 through silicide layer 122, silicide material 118, and barrier metal layer 120.

As described above, in one method of forming silicide layer in the semiconductor device consistent with the present invention, the silicide blocking layer formation process and the silicide formation process are not performed after source/drain regions 112 are formed, but silicide material 118 and barrier metal layer 120 are sequentially deposited after the formation of interlayer insulating layer 114 and contact hole 116. Silicide layer 122 is formed between source/drain region 112 and silicide material 118 by the annealing process.

Accordingly, in the formation of the silicide layer, the silicide blocking layer formation process can be omitted, and the silicide material can be deposited simultaneously with the deposition process of the barrier metal layer of the contact hole. Thus, the overall formation process can be simplified significantly.

As described above, consistent with the present invention, after the formation processes of the interlayer insulating layer and the contact hole are performed and the silicide material and the barrier metal layer are sequentially deposited, an annealing process is performed to form the silicide layer on the surface of the source/drain region. Accordingly, the silicide blocking layer formation process, which will be additionally performed after the formation of the source/drain region as described in the prior art, can be omitted.

Therefore, consistent with the present invention, at the time of the deposition process of the barrier metal layer of the contact hole, the silicide material is simultaneously deposited to form the silicide layer, and the silicide blocking layer formation process can be omitted. Consistent with the present invention, it is advantageous in that it can simplify an overall formation process of a semiconductor device and can improve margin of a formation process.

It will be apparent to those skilled in the art that various modifications may be made without departing from the spirit and scope consistent with the invention as defined by the appended claims.

What is claimed is:

1. A semiconductor device comprising:
an interlayer insulating layer formed on an entire surface of a semiconductor substrate;
a contact hole formed in the interlayer insulating layer;
a silicide material and a barrier metal layer sequentially stacked over the interlayer insulating layer including the contact hole; and
a silicide layer formed between a bottom surface of the interlayer insulating layer, which is exposed by the contact hole, and the silicide material.

2. The semiconductor device according to claim 1, wherein the silicide material has a thickness of 100 to 150 angstroms.

3. The semiconductor device according to claim 1, wherein the silicide material is formed from cobalt (Co), and
the barrier metal layer is formed from a Ti/TiN film.

4. The semiconductor device according to claim 3, wherein Ti of the barrier metal layer has a thickness of 200 to 300 angstroms and TiN of the barrier metal layer has a thickness of 50 angstroms.

5. A method of fabricating a semiconductor device having a silicide layer, comprising:
forming an interlayer insulating layer on an entire surface of a semiconductor substrate;
forming a contact hole in the interlayer insulating layer;
sequentially forming a silicide material and a barrier metal layer over the interlayer insulating layer including the contact hole; and
performing an annealing process on the interlayer insulating layer to form a silicide layer between a bottom surface of the interlayer insulating layer, which is exposed by the contact hole, and the silicide material.

6. The method according to claim 5, wherein the silicide material has a thickness of 100 to 150 angstroms.

7. The method according to claim 5, wherein
the silicide material is formed from cobalt (Co), and
the barrier metal layer is formed from a Ti/TiN film.

8. The method according to claim 7, wherein Ti of the barrier metal layer has a thickness of 200 to 300 angstroms and TiN of the barrier metal layer has a thickness of 50 angstroms.

9. The method according to claim 5, wherein the annealing process is performed by rapid thermal annealing under an inert gas atmosphere at a temperature of 700 to 900 degrees Celsius.

10. The method according to claim 5, further comprising performing an additional annealing process after forming the silicide layer.

11. The method according to claim 10, wherein the additional annealing process is performed at a temperature of 200 to 500 degrees Celsius.
